(19) United States
(12) Patent Application Publication
(10) Pub. No.: US 2026/0074617 A1
(43) Pub. Date: Mar. 12, 2026

(54) SINGLE-INPUT, MULTIPLE-OUTPUT VOLTAGE CIRCUIT IN A WIRELESS DEVICE

(71) Applicant: Qorvo US, Inc., Greensboro, NC (US)

(72) Inventor: Nadim Khlat, Ceret (FR)

(21) Appl. No.: 19/297,179

(22) Filed: Aug. 12, 2025

Related U.S. Application Data
(60) Provisional application No. 63/693,998, filed on Sep. 12, 2024.
(60) Provisional application No. 63/706,094, filed on Oct. 11, 2024.

(51) Int. Cl. H02M 3/155; H03F 3/24; H04B 1/04

(52) U.S. Cl. CPC H02M 3/155; H03F 3/245; H03F 2200/451; H04B 1/04

(57) ABSTRACT

A single-input, multiple-output (SIMO) voltage circuit in a wireless device is provided. Herein, the SIMO voltage circuit is configured to concurrently generate multiple voltages for amplifying multiple signals based on a reference voltage. In an embodiment, the reference voltage is provided by a power management integrated circuit (PMIC) and multiplexed to indicate respective targets of the voltages. Specifically, the SIMO voltage circuit includes multiple holding capacitors, each of which is repeatedly discharged and recharged to maintain a respective one of the voltages during a voltage generation cycle(s). The SIMO voltage circuit also includes multiple local control loops each configured to regulate a respective one of the voltages to thereby match the respective target indicated by the reference voltage. As such, the SIMO voltage circuit can simultaneously supply the voltages based on a single PMIC, thus making it possible to support multiple load circuits with a smaller footprint.

### RELATED APPLICATIONS

This application claims the benefit of U.S. provisional patent application Ser. No. 63/693,998, filed on Sep. 12, 2024, and U.S. provisional patent application Ser. No. 63/706,094, filed on Oct. 11, 2024, the disclosures of which are hereby incorporated herein by reference in their entireties.

### FIELD OF THE DISCLOSURE

The present disclosure is related to concurrently generating multiple voltages in a wireless device.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by such advanced wireless communication technologies as fifth-generation new-radio (5G-NR). To achieve higher data rates, a mobile communication device may employ a power amplifier(s) to amplify a radio frequency (RF) signal(s) (e.g., maintaining sufficient energy per bit) before transmission. Given that the power amplifier(s) requires a supply voltage(s) for operation, a power management integrated circuit (PMIC) is thus required to generate and provide the supply voltage(s) to the power amplifier(s).

Given that the PMIC often needs to concurrently generate multiple supply voltages for multiple power amplifiers, the PMIC typically includes multiple voltage generation circuits for modulating the multiple supply voltages. Having the multiple voltage generation circuits will inevitably increase a footprint of the PMIC, thus making it difficult to fit the PMIC into an increasingly miniaturized electronic device(s) such as a smartphone and a smart gadget. Hence, it is desirable to reduce the number of voltage generation circuits in the PMIC to help reduce the footprint of the PMIC.

### SUMMARY

Embodiments of the disclosure relate to a single-input, multiple-output (SIMO) voltage circuit in a wireless device. Herein, the SIMO voltage circuit is configured to concurrently generate multiple voltages (a.k.a. “multiple-output”) for amplifying multiple signals based on a reference voltage (a.k.a. “single-input”). In an embodiment, the reference voltage is provided by a power management integrated circuit (PMIC) in the wireless device and multiplexed to indicate respective targets of the voltages. Specifically, the SIMO voltage circuit includes multiple holding capacitors, each of which is repeatedly discharged and recharged to maintain a respective one of the voltages during a voltage generation cycle(s). The SIMO voltage circuit also includes multiple local control loops each configured to regulate a respective one of the voltages to thereby match the respective target indicated by the reference voltage. As such, the SIMO voltage circuit can simultaneously supply the voltages based on a single PMIC, thus making it possible to support multiple load circuits (e.g., power amplifiers) in the wireless device with a smaller footprint.

In one aspect, a SIMO voltage circuit is provided. The SIMO voltage circuit includes multiple holding capacitors. Each of the multiple holding capacitors is configured to maintain a respective one of multiple voltages at a respective one of multiple voltage outputs for a respective duration of a respective one of multiple voltage steps during a voltage generation cycle. The SIMO voltage circuit also includes a multi-voltage generation circuit. The multi-voltage generation circuit is configured to receive a reference voltage multiplexed to indicate a marked-up target of each of the multiple voltages in the respective one of multiple voltage steps during the voltage generation cycle. In each of the multiple voltage steps during the voltage generation cycle, the multi-voltage generation circuit is also configured to discharge a respective one of the multiple holding capacitors configured to maintain the respective one of the multiple voltages in the respective one of the multiple voltage steps. In each of the multiple voltage steps during the voltage generation cycle, the multi-voltage generation circuit is also configured to recharge concurrently all remaining ones of the multiple holding capacitors during the respective one of the multiple voltage steps. The SIMO voltage circuit also includes multiple local control loops. Each of the multiple local control loops is coupled to a respective one of the multiple holding capacitors. Each of the multiple local control loops is configured to determine a real target of the respective one of the multiple voltages from the marked-up target of the respective one of the multiple voltages. Each of the multiple local control loops is also configured to control the multi-voltage generation circuit to thereby regulate the respective one of the multiple voltages to match the determined real target.

In another aspect, a wireless device is provided. The wireless device includes a SIMO voltage circuit. The SIMO voltage circuit includes multiple holding capacitors. Each of the multiple holding capacitors is configured to maintain a respective one of multiple voltages at a respective one of multiple voltage outputs for a respective duration of a respective one of multiple voltage steps during a voltage generation cycle. The SIMO voltage circuit also includes a multi-voltage generation circuit. The multi-voltage generation circuit is configured to receive a reference voltage multiplexed to indicate a marked-up target of each of the multiple voltages in the respective one of multiple voltage steps during the voltage generation cycle. In each of the multiple voltage steps during the voltage generation cycle, the multi-voltage generation circuit is also configured to discharge a respective one of the multiple holding capacitors configured to maintain the respective one of the multiple voltages in the respective one of the multiple voltage steps. In each of the multiple voltage steps during the voltage generation cycle, the multi-voltage generation circuit is also configured to recharge concurrently all remaining ones of the multiple holding capacitors during the respective one of the multiple voltage steps. The SIMO voltage circuit also includes multiple local control loops. Each of the multiple local control loops is coupled to a respective one of the multiple holding capacitors. Each of the multiple local control loops is configured to determine a real target of the respective one of the multiple voltages from the marked-up target of the respective one of the multiple voltages. Each of the multiple local control loops is also configured to control the multi-voltage generation circuit to thereby regulate the respective one of the multiple voltages to match the determined real target.

In another aspect, a method for concurrently generating multiple voltages is provided. The method includes receiving a reference voltage multiplexed to indicate a respective one of multiple marked-up target voltages of a respective one of multiple voltages in a respective one of multiple voltage steps during a voltage generation cycle. The method also includes discharging, in each of the multiple voltage steps during the voltage generation cycle, a respective one of multiple holding capacitors configured to maintain the respective one of the multiple voltages in the respective one of the multiple voltage steps. The method also includes recharging, in each of the multiple voltage steps during the voltage generation cycle, concurrently all remaining ones of the multiple holding capacitors during the respective one of the multiple voltage steps. The method also includes determining a respective one of multiple real target voltages of the respective one of the multiple voltages from the respective one of the multiple marked-up target voltages. The method also includes regulating the respective one of the multiple voltages to match the respective one of the multiple real target voltages.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary wireless device wherein a single-input, multiple-output (SIMO) voltage circuit is configured to concurrently generate multiple voltages based on a reference voltage provided by a power management integrated circuit (PMIC) in the wireless device;

FIG. 2 is a schematic diagram providing an exemplary illustration of the PMIC in the wireless device of FIG. 1;

FIG. 3 is a schematic diagram providing an exemplary illustration of the SIMO voltage circuit in the wireless device of FIG. 1, which is configured to concurrently supply the voltages during a voltage generation cycle(s);

FIGS. 4A and 4B are schematic diagrams providing exemplary illustrations of the voltage generation cycle(s) in FIG. 1;

FIG. 5 is a schematic diagram illustrating a multi-voltage generation circuit in the SIMO voltage circuit that is configured to concurrently supply multiple voltages during the voltage generation cycle(s);

FIG. 6 is a schematic diagram of an exemplary communication device that is functionally equivalent to the wireless device of FIG. 1; and

FIG. 7 is a flowchart of an exemplary process for generating the multiple voltages in the wireless device of FIG. 1.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to a single-input, multiple-output (SIMO) voltage circuit in a wireless device. Herein, the SIMO voltage circuit is configured to concurrently generate multiple voltages (a.k.a. “multiple-output”) for amplifying multiple signals based on a reference voltage (a.k.a. “single-input”). In an embodiment, the reference voltage is provided by a power management integrated circuit (PMIC) in the wireless device and multiplexed to indicate respective targets of the voltages. Specifically, the SIMO voltage circuit includes multiple holding capacitors, each of which is repeatedly discharged and recharged to maintain a respective one of the voltages during a voltage generation cycle(s). The SIMO voltage circuit also includes multiple local control loops each configured to regulate a respective one of the voltages to thereby match the respective target indicated by the reference voltage. As such, the SIMO voltage circuit can simultaneously supply the voltages based on a single PMIC, thus making it possible to support multiple load circuits (e.g., power amplifiers) in the wireless device with a smaller footprint.

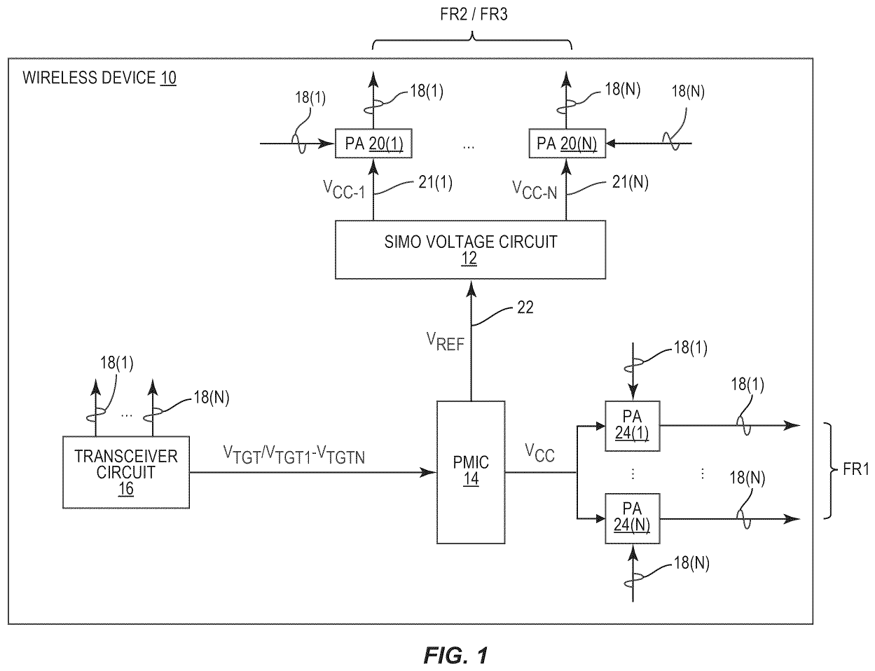

FIG. 1 is a schematic diagram of an exemplary wireless device 10 wherein a single-input, multiple-output (SIMO) voltage circuit 12 is configured to concurrently generate multiple voltages V_{CC-1}-V_{CC-N} based on a reference voltage V_{REF} provided by a power management integrated circuit (PMIC) 14 in the wireless device 10. The wireless device 10 includes a transceiver circuit 16, which can generate one or more radio frequency (RF) signals 18(1)-18(N) for concurrent transmission in frequency range one (FR1) (≤6 GHz), frequency range two (FR2) (>24.25 GHz), and/or frequency range three (FR3) (≥7.15 GHz and ≤24.25 GHz).

Specifically, the wireless device 10 includes one or more power amplifier circuits 20(1)-20(N), each of which is coupled to the SIMO voltage circuit 12 via a respective one of one or more voltage lines 21(1)-21(N) and configured to amplify a respective one of the RF signals 18(1)-18(N) for transmission in FR2 or FR3. In this regard, the transceiver circuit 16 will provide one or more target voltages V_{TGT1}-V_{TGTN} to the PMIC 14. Accordingly, the PMIC 14 is configured to generate the reference voltage V_{REF} based on the target voltages V_{TGT1}-V_{TGTN} and provide the reference voltage V_{REF} to the SIMO voltage circuit 12 via a conductive trace 22. In an embodiment, the reference voltage V_{REF} is a multiplexed voltage that indicates respective targets of the voltages V_{CC-1}-V_{CC-N}. Accordingly, the SIMO voltage circuit 12 generates and provides the voltages V_{CC-1}-V_{CC-N} to the power amplifier circuits 20(1)-20(N) for amplifying the RF signals 18(1)-18(N) for transmission in FR2 or FR3.

Alternatively, when the wireless device 10 needs to transmit the RF signals 18(1)-18(N) in FR1, the transceiver circuit 16 will provide a modulated target voltage V_{TGT} to the PMIC 14. Accordingly, the PMIC 14 will instead generate a modulated voltage V_{CC}, such as an envelope tracking (ET) or average power tracking (APT) voltage, based on the modulated target voltage V_{TGT}. Herein, the wireless device 10 further includes one or more second power amplifier circuits 24(1)-24(N), each of which can be configured to amplify a respective one of the RF signals 18(1)-18(N) based on the modulated voltage V_{CC} for transmission in FR1.

In an embodiment, the wireless device 10 is configured to transmit the RF signals 18(1)-18(N) in one of FR1, FR2, and FR3. In this regard, the PMIC 14 will only generate and provide the reference voltage V_{REF} to the SIMO voltage circuit 12 when the RF signals 18(1)-18(N) are transmitted in FR2 or FR3. In other words, the PMIC 14 will not generate the reference voltage V_{REF} when the wireless device 10 is configured to transmit the RF signals 18(1)-18(N) in FR1. In an embodiment, the transceiver circuit 16, which has first-hand knowledge of how the RF signals 18(1)-18(N) are going to be transmitted, may be configured to control the PMIC 14 to either generate the reference voltage V_{REF} or the modulated voltage V_{CC}.

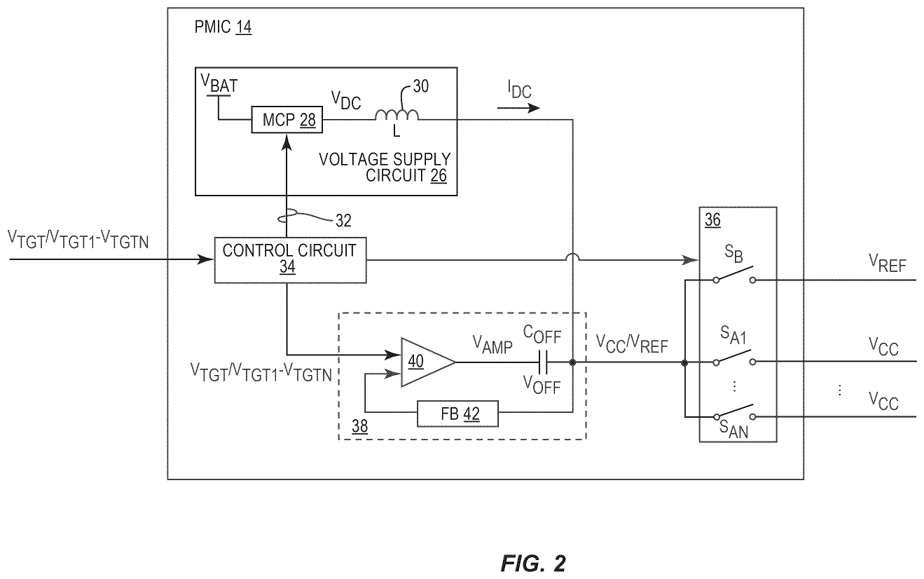

FIG. 2 is a schematic diagram providing an exemplary illustration of the PMIC 14 in the wireless device 10 of FIG. 1. Common elements between FIGS. 1 and 2 are shown therein with common element numbers and will not be re-described herein.

The PMIC 14 includes a voltage supply circuit 26, which further includes a multi-level charge pump (MCP) 28 coupled in series to a power inductor 30. The MCP 28 is configured to generate a low-frequency voltage V_{DC} as a function of a battery voltage V_{BAT}. In an embodiment, the MCP 28 can be a buck-boost voltage converter that can toggle between a buck mode and a boost mode in accordance with a duty cycle signal 32. The duty cycle signal 32 may be determined by a control circuit 34 in accordance with the target voltages V_{TGT1}-V_{TGTN}. Accordingly, the power inductor 30 can induce a low-frequency current I_{DC} based on the low-frequency voltage V_{DC}.

The voltage supply circuit 26 is coupled to a switch circuit 36, which includes one or more first switches S_{A1}-S_{AN} and a second switch S_{B}. The PMIC 14 also includes a voltage modulation circuit 38. In an embodiment, the voltage modulation circuit 38 includes a voltage amplifier 40, an offset capacitor C_{OFF}, and a feedback loop 42. The voltage amplifier 40 is configured to generate a modulated initial voltage V_{AMP} based on a modulated target voltage V_{TGT}. The offset capacitor C_{OFF}, which is coupled between the voltage amplifier 40 and each of the first switches S_{A1}-S_{AN} and the second switch S_{B}, is configured to raise the modulated initial voltage V_{AMP} by an offset voltage V_{OFF} to thereby generate the reference voltage V_{REF} (for transmission in FR2 or FR3) or the modulated voltage V_{CC} (for transmission in FR1). The feedback loop 42 is configured to cause the voltage amplifier 40 to adjust the modulated initial voltage V_{AMP} to thereby ensure that the modulated voltage V_{CC} tracks closely to track the modulated target voltage V_{TGT}.

When the wireless device 10 is configured to transmit the RF signals 18(1)-18(N) in FR1, the control circuit 34 will provide the modulated target voltage V_{TGT} to the voltage amplifier 40. The control circuit 34 will also control the switch circuit 36 to close any one or more of the first switches S_{A1}-S_{AN}, while leaving the second switch S_{B} open to thereby provide the modulated voltage V_{CC} to any one or more of the second power amplifier circuits 24(1)-24(N) for amplifying the RF signals 18(1)-18(N) for transmission in FR1.

In contrast, when the wireless device 10 is configured to transmit the RF signals 18(1)-18(N) in FR2 or FR3, the control circuit 34 will multiplex the target voltages V_{TGT1}-V_{TGTN} and provide the multiplexed target voltages V_{TGT1}-V_{TGTN} to the voltage amplifier 40. The control circuit 34 will also control the switch circuit 36 to close the second switch S_{B}, while leaving all of the first switches SA1-S_{AN} open. As a result, the PMIC 14 will generate the reference voltage V_{REF} as expressed in equation (Eq. 1) below and provide the reference voltage V_{REF} to the SIMO voltage circuit 12.

V_{REF}=L×Dv_{DC}/Dt (eq. 1)

In the above equation (Eq. 1), L represents an inductance of the power inductor 30, whereas dV_{DC}/dt represents a rate of change of the low-frequency voltage V_{DC}, as determined by the duty cycle signal 32. Accordingly, the SIMO voltage circuit 12 can concurrently generate and provide the voltages V_{CC-1}-V_{CC-N} to the power amplifier circuits 20(1)-20(N) for amplifying the RF signals 18(1)-18(N) for transmission in FR2 or FR3.

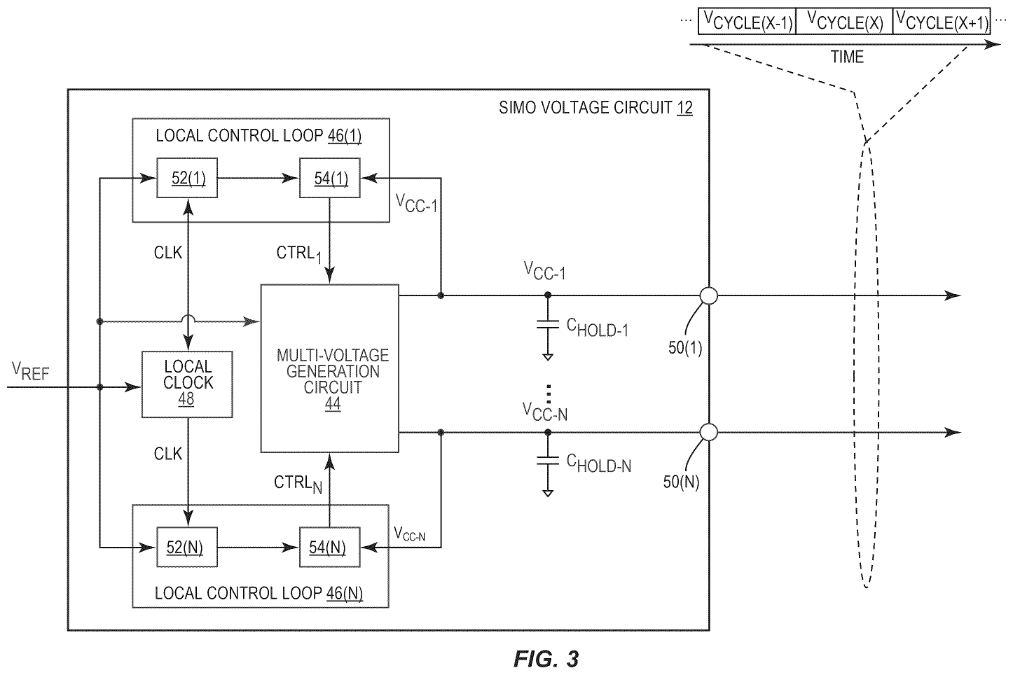

FIG. 3 is a schematic diagram providing an exemplary illustration of the SIMO voltage circuit 12 in the wireless device 10 of FIG. 1, which is configured to concurrently supply the voltages V_{CC-1}-V_{CC-N} during each of multiple voltage generation cycles V_{CYCLE(X-1)}, V_{CYCLE(X)}, V_{CYCLE(X+1)}. Common elements between FIGS. 1 and 3 are shown therein with common element numbers and will not be re-described herein.

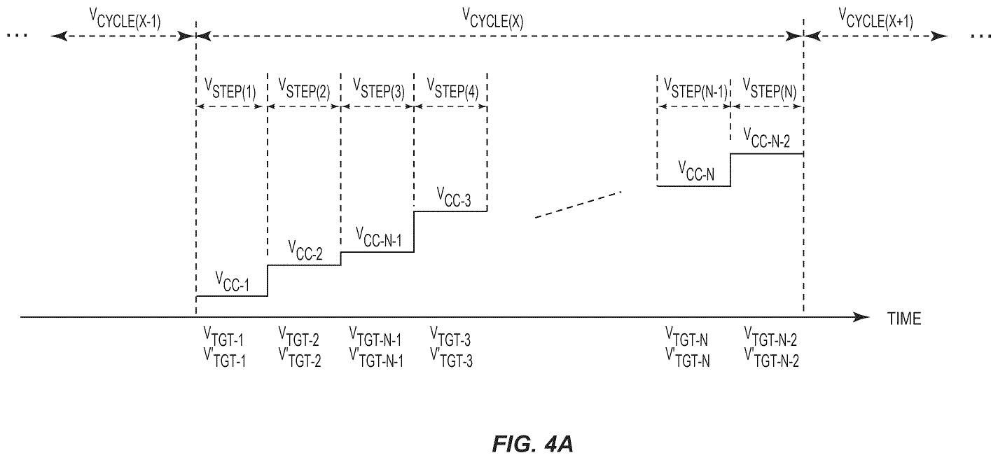

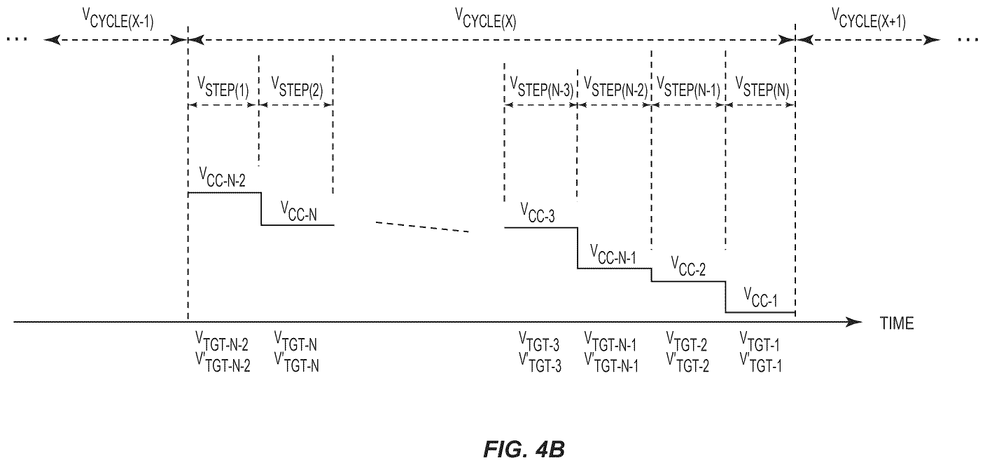

Herein, the voltage generation cycles V_{CYCLE(X-1)}, V_{CYCLE(X)}, V_{CYCLE(X+1)} represent any three consecutive voltage generation cycles among an infinite number of voltage generation cycles, which are omitted herein for simplicity. FIGS. 4A and 4B are schematic diagrams providing exemplary illustrations of the voltage generation cycles V_{CYCLE(X-1)}, V_{CYCLE(X)}, V_{CYCLE(X+1)} in FIG. 3. Common elements between FIGS. 3 and 4A-4B are shown therein with common element numbers and will not be re-described herein.

In an embodiment, each of the voltage generation cycles V_{CYCLE(X-1)}, V_{CYCLE(X)}, V_{CYCLE(X+1)} is further divided into multiple voltage steps V_{STEP(1)}-V_{STEP(N)}. Each of the voltage steps V_{STEP(1)}-V_{STEP(N)} is used to generate one of the voltages V_{CC-1}-V_{CC-N}. Notably, although a total number of the voltage steps V_{STEP(1)}-V_{STEP(N)} is identical to the total number of the voltages V_{CC-1}-V_{CC-N}, it is not necessary for the voltages V_{CC-1}-V_{CC-N} to be generated in the same order as the voltage steps V_{STEP(1)}-V_{STEP(N)}. Rather, the SIMO voltage circuit 12 can be configured to generate the voltages V_{CC-1}-V_{CC-N} monotonically to minimize a relative voltage change between each pair of the voltages V_{CC-1}-V_{CC-N}. In this regard, the voltages V_{CC-1}-V_{CC-N} as generated by the SIMO voltage circuit 12 can be out of order from the voltage steps V_{STEP(1)}-V_{STEP(N)}. Specifically, FIG. 4A illustrates that the voltages V_{CC-1}-V_{CC-N} are generated in an ascending order, and FIG. 4B illustrates that the voltages V_{CC-1}-V_{CC-N} are generated in a descending order.

In an embodiment, the SIMO voltage circuit 12 may be configured to generate the voltages V_{CC-1}-V_{CC-N} based on both the ascending and the descending orders. In one non-limiting example, the SIMO voltage circuit 12 may be configured to generate the voltages V_{CC-1}-V_{CC-N} in the ascending order in a preceding one of the voltage generation cycles V_{CYCLE(X-1)}, V_{CYCLE(X)}, V_{CYCLE(X+1)} (e.g., V_{CYCLE(X)}) and then generate the voltages V_{CC-1}-V_{CC-N} in the descending order in a succeeding one of the voltage generation cycles V_{CYCLE(X-1)}, V_{CYCLE(X)}, V_{CYCLE(X+1)} (e.g., V_{CYCLE(X+1)}). In another non-limiting example, the SIMO voltage circuit 12 may be configured to generate the voltages V_{CC-1}-V_{CC-N} in the descending order in a preceding one of the voltage generation cycles V_{CYCLE(X-1)}, V_{CYCLE(X)}, V_{CYCLE(X+1)} (e.g., V_{CYCLE(X)}) and then generate the voltages V_{CC-1}-V_{CC-N} in the ascending order in a succeeding one of the voltage generation cycles V_{CYCLE(X-1)}, V_{CYCLE(X)}, V_{CYCLE(X+1)} (e.g., V_{CYCLE(X+1)}).

As mentioned earlier, the reference voltage V_{REF} is multiplexed to indicate the respective targets V_{TGT1}-V_{TGTN} of the voltages V_{CC-1}-V_{CC-N}. In this regard, for each of the voltage generation cycles V_{CYCLE(X-1)}, V_{CYCLE(X)}, V_{CYCLE(X+1)}, the target voltages V_{TGT1}-V_{TGTN} must be multiplexed in the reference voltage V_{REF} in the same ascending or descending order as the voltages V_{CC-1}-V_{CC-N}. In this regard, in the example of FIG. 4A, the target voltages V_{TGT1}-V_{TGTN} must be multiplexed in the reference voltage V_{REF} in the order of V_{TGT-1}, V_{TGT-2}, V_{TGT-N-1}, V_{TGT-3}, . . . , V_{TGT-N}, V_{TGT-N-2}, whereas in the example of FIG. 4B, the target voltages V_{TGT1}-V_{TGTN} must be multiplexed in the reference voltage V_{REF} in the order of V_{TGT-N-2}, V_{TGT-N}, . . . , V_{TGT-3}, V_{TGT-N-1}, . . . V_{TGT-2}, V_{TGT-1}.

Recall in FIG. 1 that the PMIC 14 is configured to provide the reference voltage V_{REF} to the SIMO voltage circuit 12 via the conductive trace 22, and the SIMO voltage circuit 12 is coupled to each of the power amplifier circuits 20(1)-20(N) via a respective one of the voltage lines 21(1)-21(N). Notably, the conductive trace 22 and the voltage lines 21(1)-21(N) can collectively cause each of the voltages V_{CC-1}-V_{CC-N} to slightly drop at a respective one of the power amplifier circuits 20(1)-20(N). In this regard, to help compensate for the drop in each of the voltages V_{CC-1}-V_{CC-N}, each of the target voltages V_{TGT1}-V_{TGTN} is first marked up by a headroom V_{HR} to generate a respective one of one or more marked-up target voltages V′_{TGT1}-V′_{TGTN} before being multiplexed into the reference voltage V_{REF}. The marked-up target voltages V′_{TGT1}-V′_{TGTN} can each be determined by equation (Eq. 2) below.

V′_{TGTi}=V_{TGTi}+V_{HR}(1≤i≤N) (Eq. 2)

In the equation (Eq. 2), V′_{TGTi} represents a respective one of the marked-up target voltages V′_{TGT1}-V′_{TGTN}, V_{TGTi} represents a respective one of the target voltages V_{TGT1}-V_{TGTN}, and V_{HR} represents the headroom. In an embodiment, the headroom V_{HR} is so determined to compensate for the worst drop among the voltages V_{CC-1}-V_{CC-N}. Accordingly, the SIMO voltage circuit 12 will instead receive the reference voltage V_{REF} that is multiplexed to indicate the marked-up target voltages V′_{TGT1}-V′_{TGTN}. Understandably, the marked-up target voltages V′_{TGT1}-V′_{TGTN} are also multiplexed in the reference voltage V_{REF} in the same ascending or descending order as the voltages V_{CC-1}-V_{CC-N}.

With reference back to FIG. 3, the SIMO voltage circuit 12 includes a multi-voltage generation circuit 44, one or more local control loops 46(1)-46(N), and a local clock circuit 48. In an embodiment, the multi-voltage generation circuit 44, the local control loops 46(1)-46(N), and the local clock circuit 48 are all configured to receive and operate based on the reference voltage V_{REF}.

The SIMO voltage circuit 12 also includes multiple holding capacitors C_{HOLD-1}-C_{HOLD-N}, each of which is configured to supply (a.k.a. maintain) a respective one of the voltages V_{CC-1}-V_{CC-N} at a respective one of one or more voltage outputs 50(1)-50(N) for a respective duration of the voltage steps V_{STEP(1)}-V_{STEP(N)} in each of the voltage generation cycles V_{CYCLE(X-1)}, V_{CYCLE(X)}, V_{CYCLE(X+1)}. In other words, in each of the voltage generation cycles V_{CYCLE(X-1)}, V_{CYCLE(X)}, V_{CYCLE(X+1)}, each of the holding capacitors C_{HOLD-1}-C_{HOLD-N} is either discharged to supply the respective level of the respective one of the voltages V_{CC-1}-V_{CC-N} or recharged to maintain the respective level of the respective one of the voltages V_{CC-1}-V_{CC-N} for the respective duration of the voltage steps V_{STEP(1)}-V_{STEP(N)}.

According to an embodiment of the present disclosure, during each of the voltage steps V_{STEP(1)}-V_{STEP(N)} in any of the voltage generation cycles V_{CYCLE(X-1)}, V_{CYCLE(X)}, V_{CYCLE(X+1)}, only one of the holding capacitors C_{HOLD-1}-C_{HOLD-N} is discharged to supply the respective one of the voltages V_{CC-1}-V_{CC-N}, while the rest of the holding capacitors C_{HOLD-1}-C_{HOLD-N} are concurrently recharged to maintain the respective ones of the voltages V_{CC-1}-V_{CC-N}. As such, the SIMO voltage circuit 12 can make all of the voltages V_{CC-1}-V_{CC-N} concurrently available based exclusively on the reference voltage V_{REF} provided by the PMIC 14, thus making it possible to reduce the footprint of the SIMO voltage circuit 12.

Moreover, since each of the holding capacitors C_{HOLD-1}-C_{HOLD-N} is recharged in all but one of the voltage steps V_{STEP(1)}-V_{STEP(N)} in each of the voltage generation cycles V_{CYCLE(X-1)}, V_{CYCLE(X)}, V_{CYCLE(X+1)}, each of the holding capacitors C_{HOLD-1}-C_{HOLD-N} can be recharged rather frequently to hold the respective level of the respective one of the voltages V_{CC-1}-V_{CC-N}. As such, it is possible to make the holding capacitors C_{HOLD-1}-C_{HOLD-N} smaller to help further reduce the footprint of the SIMO voltage circuit 12. Further, by making the holding capacitors C_{HOLD-1}-C_{HOLD-N} smaller, it is also possible to reduce the charging time of the holding capacitors C_{HOLD-1}-C_{HOLD-N} to thereby support faster adaptation of the voltages V_{CC-1}-V_{CC-N}.

Given that the marked-up target voltages V′_{TGT1}-V′_{TGTN} are each marked by the headroom V_{HR} that represents the worst drop among the voltages V_{CC-1}-V_{CC-N}, each of the local control loops 46(1)-46(N) is first configured to determine a respective real target V_{TGT-REALi} (1≤i≤N) from a respective one of the marked-up target voltages V′_{TGT1}-V′_{TGTN}. In an embodiment, the respective real target V_{TGT-REALi} may be determined according to equation (Eq. 3) below.

V_{TGT-REALi}=V′_{TGTi}−V_{OFFSETi}(1≤i≤N) (eq. 3)

In the equation (Eq. 3), V_{TGT-REALi} represents a respective one of the real target voltages V_{TGT-REAL1}-V_{TGT-REALN}, V′_{TGTi} represents a respective one of the marked-up target voltages V′_{TGT1}-V′_{TGTN}, and V_{OFFSETi} represents a respective one of one or more offset values V_{OFFSET1}-V_{OFFSETN}. Each of the offset values V_{OFFSET1}-V_{OFFSETN} is so determined to provide an offset between an expected drop in a respective one of the voltages V_{CC-1}-V_{CC-N} and the headroom V_{HR} that was included in each of the marked-up target voltages V′_{TGT1}-V′_{TGTN}. In one embodiment, the respective one of the offset values V_{OFFSET1}-V_{OFFSETN} for each of the voltages V_{CC-1}-V_{CC-N} may be predetermined based on a specific layout of the wireless device 10 and prestored in each of the local control loops 46(1)-46(N). In an alternative embodiment, the respective one of the offset values V_{OFFSET1}-V_{OFFSETN} may be communicated to each of the local control loops 46(1)-46(N) via methods that are outside the scope of the present disclosure.

Each of the local control loops 46(1)-46(N) is further configured to receive a respective feedback of the voltages V_{CC-1}-V_{CC-N}, compare the respective feedback against a respective one of the real target voltages V_{TGT-REAL1}-V_{TGT-REALN}, and control the multi-voltage generation circuit 44 to thereby regulate a respective one of the voltages V_{CC-1}-V_{CC-N} to match the determined one of the real target voltages V_{TGT-REAL1}-V_{TGT-REALN}. Herein, each of the local control loops 46(1)-46(N) may control the multi-voltage generation circuit 44 via a respective one of one or more control signals CTRL₁-CTRL_{N}.

In an embodiment, each of the local control loops 46(1)-46(N) can include a respective one of one or more demultiplexers 52(1)-52(N) and a respective one of one or more loop controllers 54(1)-54(N). Each of the demultiplexers 52(1)-52(N) is configured to demultiplex the reference voltage V_{REF} to thereby obtain the respective one of the marked-up target voltages V′_{TGT1}-V′_{TGTN} based on a clock signal CLK provided by the local clock circuit 48. Each of the loop controllers 54(1)-54(N) is configured to determine the respective one of the real target voltages V_{TGT-REAL1}-V_{TGT-REALN} from the respective one of the marked-up target voltages V′_{TGT1}-V′_{TGTN}. Accordingly, each of the loop controllers 54(1)-54(N) can generate the respective one of the control signals C_{TRL1}-C_{TRLN} to thereby control the multi-voltage generation circuit 44 to regulate the respective one of the voltages V_{CC-1}-V_{CC-N} to match the respective one of the real target voltages V_{TGT-REAL1}-V_{TGT-REALN}.

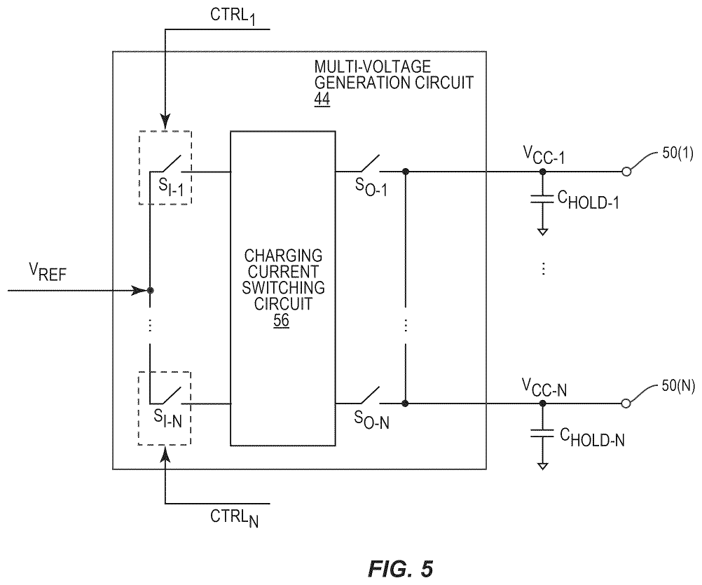

FIG. 5 is a schematic diagram providing an exemplary illustration of the multi-voltage generation circuit 44 in the SIMO voltage circuit 12 of FIG. 3. Common elements between FIGS. 3 and 5 are shown therein with common element numbers and will not be re-described herein.

In an embodiment, the multi-voltage generation circuit 44 includes multiple input switches S_{I-1}-S_{I-N}, multiple output switches S_{O-1}-S_{O-N}, and a charging current switching circuit 56. Herein, each of the input switches S_{I-1}-S_{I-N} corresponds to a respective one of the output switches S_{O-1}-S_{O-N}. Each of the output switches S_{O-1}-S_{O-N} is coupled to a respective one of the holding capacitors C_{HOLD-1}-C_{HOLD-N}. The charging current switching circuit 56 is coupled between the input switches S_{I-1}-S_{I-N} and the output switches S_{O-1}-S_{O-N}.

Herein, each of the holding capacitors C_{HOLD-1}-C_{HOLD-N} will be discharged when the respective one of the input switches S_{I-1}-S_{I-N} is closed and the respective one of the output switches S_{O-1}-S_{O-N} is opened. In contrast, each of the holding capacitors C_{HOLD-1}-C_{HOLD-N} will be recharged when the respective one of the input switches S_{I-1}-S_{I-N} is opened and the respective one of the output switches S_{O-1}-S_{O-N} is closed. As an example, when the input switch S_{I-1} is closed and the output switch S_{O-1} is opened, the holding capacitor C_{HOLD-1} will be discharged to supply the voltage V_{CC-1}. In the meantime, if the rest of the input switches S_{I-2}-S_{I-N} are opened and the rest of the output switches S_{O-2}-S_{O-N} are closed, the rest of the holding capacitors C_{HOLD-2}-C_{HOLD-N} will be concurrently recharged to hold the respective voltages V_{CC-2}-V_{CC-N}.

Herein, each of the input switches S_{I-1}-S_{I-N} can be controlled via a respective one of the control signals CTRL₁-CTRL_{N}. In a non-limiting example, the input switches S_{I-1}-S_{I-N} can each be implemented by a transistor. As such, each of the control signals CTRL₁-CTRL_{N} can cause a respective one of the input switches S_{I-1}-S_{I-N} to function either as a switch or a low-dropout (LDO) regulator. In this regard, each of the control signals CTRL₁-CTRL_{N} can be so generated to control an impedance of the respective one of the input switches S_{I-1}-S_{I-N} to thereby regulate the respective one of the voltages V_{CC-1}-V_{CC-N} to match the respective one of the real target voltages V_{TGT-REAL1}-V_{TGT-REALN}. For detailed operating examples as to how the multi-voltage generation circuit 44 can concurrently generate and regulate the voltages V_{CC-1}-V_{CC-N} based on the reference voltage V_{REF}, please refer to U.S. Patent Application Publication Number 2025/0047191 A1, entitled “MULTI-VOLTAGE POWER MANAGEMENT INTEGRATED CIRCUIT.”

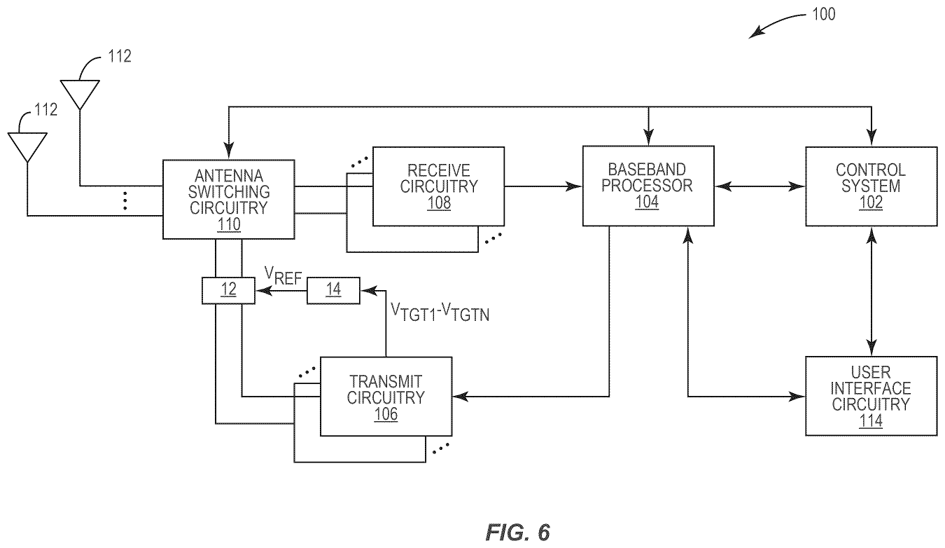

The SIMO voltage circuit 12 in the wireless device 10 of FIG. 1 can be provided in a communication device to support the embodiments described above. In this regard, FIG. 6 is a schematic diagram of an exemplary communication device 100 wherein the SIMO voltage circuit 12 in the wireless device 10 of FIG. 1 can be provided.

Herein, the communication device 100 can be any type of communication device, such as mobile terminals, smart watches, tablets, computers, navigation devices, access points, and like wireless communication devices that support wireless communications, such as cellular, wireless local area network (WLAN), Bluetooth, and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

In an embodiment, the SIMO voltage circuit 12 may be provided between the transmit circuitry 106 and the antenna switching circuitry 110. The PMIC 14 may receive the target voltages V_{TGT1}-V_{TGTN} from the transmit circuitry 106 and provide the reference voltage V_{REF} to the SIMO voltage circuit 12.

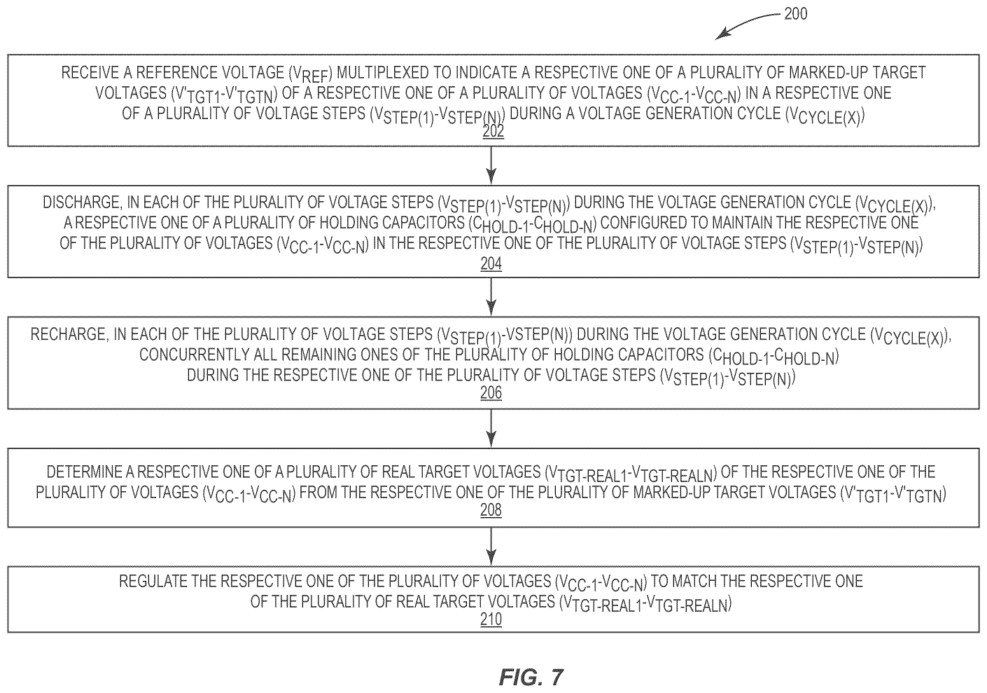

In an embodiment, the SIMO voltage circuit 12 in the wireless device 10 of FIG. 1 can be configured to concurrently generate the voltages V_{CC-1}-V_{CC-N} in accordance with a process. In this regard, FIG. 7 is a flowchart of an exemplary process 200 for generating the voltages V_{CC-1}-V_{CC-N} in the wireless device 10 of FIG. 1.

Herein, the process 200 includes receiving the reference voltage V_{REF} multiplexed to indicate a respective one of the marked-up target voltages V′_{TGT1}-V′_{TGTN} of a respective one of the voltages V_{CC-1}-V_{CC-N} in a respective one of the voltage steps V_{STEP(1)}-V_{STEP(N)} during a voltage generation cycle V_{CYCLE(X)} (step 202). The process 200 also includes discharging, in each of the voltage steps V_{STEP(1)}-V_{STEP(N)} during the voltage generation cycle V_{CYCLE(X)}, a respective one of the holding capacitors C_{HOLD-1}-C_{HOLD-N} configured to maintain the respective one of the voltages V_{CC-1}-V_{CC-N} in the respective one of the voltage steps V_{STEP(1)}-V_{STEP(N)} (step 204). The process 200 also includes recharging, in each of the voltage steps V_{STEP(1)}-V_{STEP(N)} during the voltage generation cycle V_{CYCLE(X)}, concurrently all remaining ones of the holding capacitors C_{HOLD-1}-C_{HOLD-N} during the respective one of the voltage steps V_{STEP(1)}-V_{STEP(N)} (step 206). The process 200 also includes determining a respective one of the real target voltages V_{TGT-REAL1}-V_{TGT-REALN} of the respective one of the voltages V_{CC-1}-V_{CC-N} from the respective one of the marked-up target voltages V′_{TGT1}-V′_{TGTN} (step 208). The process 200 also includes regulating the respective one of the voltages V_{CC-1}-V_{CC-N} to match the respective one of the real target voltages V_{TGT-REAL1}-V_{TGT-REALN} (step 210).

Those skilled in the art will recognize improvements and modifications to the preferred embodiments of the present disclosure. All such improvements and modifications are considered within the scope of the concepts disclosed herein and the claims that follow.

What is claimed is:

1. A single-input, multiple-output (SIMO) voltage circuit comprising:
a plurality of holding capacitors each configured to maintain a respective one of a plurality of voltages at a respective one of a plurality of voltage outputs for a respective duration of a respective one of a plurality of voltage steps during a voltage generation cycle;
a multi-voltage generation circuit configured to:
receive a reference voltage multiplexed to indicate a marked-up target of each of the plurality of voltages in a respective one of the plurality of voltage steps during the voltage generation cycle;
in each of the plurality of voltage steps during the voltage generation cycle:
discharge a respective one of the plurality of holding capacitors configured to maintain the respective one of the plurality of voltages in the respective one of the plurality of voltage steps; and
recharge concurrently all remaining ones of the plurality of holding capacitors during the respective one of the plurality of voltage steps; and
a plurality of local control loops each coupled to a respective one of the plurality of holding capacitors and configured to:
determine a real target of the respective one of the plurality of voltages from the marked-up target of the respective one of the plurality of voltages; and
control the multi-voltage generation circuit to thereby regulate the respective one of the plurality of voltages to match the determined real target.

2. The SIMO voltage circuit of claim 1, wherein the marked-up target of each of the plurality of voltages is equal to the real target of the respective one of the plurality of voltages plus a headroom voltage.

3. The SIMO voltage circuit of claim 1, wherein each of the plurality of local control loops comprises:
a respective demultiplexer configured to demultiplex the reference voltage to thereby obtain the marked-up target of the respective one of the plurality of voltages; and
a respective loop controller configured to:
determine the real target of the respective one of the plurality of voltages from the marked-up target of the respective one of the plurality of voltages; and
control the multi-voltage generation circuit to thereby regulate the respective one of the plurality of voltages to match the determined real target.

4. The SIMO voltage circuit of claim 3, wherein the respective loop controller in each of the plurality of local control loops is further configured to determine the real target of the respective one of the plurality of voltages by subtracting a respective offset value from the marked-up target of the respective one of the plurality of voltages.

5. The SIMO voltage circuit of claim 1, wherein the multi-voltage generation circuit comprises:
a plurality of input switches each corresponding to a respective one of the plurality of holding capacitors and coupled to a common node configured to receive the reference voltage in each of the plurality of voltage steps;
a plurality of output switches each coupled to a respective one of the plurality of holding capacitors; and
a charging current switching circuit provided in between the plurality of input switches and the plurality of output switches.

6. The SIMO voltage circuit of claim 5, wherein, in each of the plurality of voltage steps during the voltage generation cycle, the multi-voltage generation circuit is further configured to:
open a respective one of the plurality of output switches coupled to the respective one of the plurality of holding capacitors configured to maintain the respective one of the plurality of voltages in the respective one of the plurality of voltage steps and close a respective one of the plurality of input switches corresponding to the respective one of the plurality of output switches to thereby discharge the respective one of the plurality of holding capacitors to maintain the respective one of the plurality of voltages; and
open all remaining ones of the plurality of input switches and close all remaining ones of the plurality of output switches to thereby recharge all the remaining ones of the plurality of holding capacitors.

7. The SIMO voltage circuit of claim 6, wherein each of the plurality of local control loops is further configured to control the respective one of the plurality of input switches that is closed during the respective one of the plurality of voltage steps to thereby regulate the respective one of the plurality of voltages to match the determined real target.

8. A wireless device comprising:
a single-input, multiple-output (SIMO) voltage circuit comprising:
a plurality of holding capacitors each configured to maintain a respective one of a plurality of voltages at a respective one of a plurality of voltage outputs for a respective duration of a respective one of a plurality of voltage steps during a voltage generation cycle;
a multi-voltage generation circuit configured to:
receive a reference voltage multiplexed to indicate a marked-up target of each of the plurality of voltages in the respective one of the plurality of voltage steps during the voltage generation cycle;
in each of the plurality of voltage steps during the voltage generation cycle:
discharge a respective one of the plurality of holding capacitors configured to maintain the respective one of the plurality of voltages in the respective one of the plurality of voltage steps; and
recharge concurrently all remaining ones of the plurality of holding capacitors during the respective one of the plurality of voltage steps; and
a plurality of local control loops each coupled to a respective one of the plurality of holding capacitors and configured to:
determine a real target of the respective one of the plurality of voltages from the marked-up target of the respective one of the plurality of voltages; and
control the multi-voltage generation circuit to thereby regulate the respective one of the plurality of voltages to match the determined real target.

9. The wireless device of claim 8, wherein the marked-up target of each of the plurality of voltages is equal to the real target of the respective one of the plurality of voltages plus a headroom voltage.

10. The wireless device of claim 8, wherein each of the plurality of local control loops comprises:
a respective demultiplexer configured to demultiplex the reference voltage to thereby obtain the marked-up target of the respective one of the plurality of voltages; and
a respective loop controller configured to:
determine the real target of the respective one of the plurality of voltages from the marked-up target of the respective one of the plurality of voltages; and
control the multi-voltage generation circuit to thereby regulate the respective one of the plurality of voltages to match the determined real target.

11. The wireless device of claim 10, wherein the respective loop controller in each of the plurality of local control loops is further configured to determine the real target of the respective one of the plurality of voltages by subtracting a respective offset value from the marked-up target of the respective one of the plurality of voltages.

12. The wireless device of claim 8, wherein the multi-voltage generation circuit comprises:
a plurality of input switches each corresponding to a respective one of the plurality of holding capacitors and coupled to a common node configured to receive the reference voltage in each of the plurality of voltage steps;
a plurality of output switches each coupled to a respective one of the plurality of holding capacitors; and
a charging current switching circuit provided in between the plurality of input switches and the plurality of output switches.

13. The wireless device of claim 12, wherein, in each of the plurality of voltage steps during the voltage generation cycle, the multi-voltage generation circuit is further configured to:
open a respective one of the plurality of output switches coupled to the respective one of the plurality of holding capacitors configured to maintain the respective one of the plurality of voltages in the respective one of the plurality of voltage steps and close a respective one of the plurality of input switches corresponding to the respective one of the plurality of output switches to thereby discharge the respective one of the plurality of holding capacitors to maintain the respective one of the plurality of voltages; and
open all remaining ones of the plurality of input switches and close all remaining ones of the plurality of output switches to thereby recharge all the remaining ones of the plurality of holding capacitors.

14. The wireless device of claim 13, wherein each of the plurality of local control loops is further configured to control the respective one of the plurality of input switches that is closed during the respective one of the plurality of voltage steps to thereby regulate the respective one of the plurality of voltages to match the determined real target.

15. The wireless device of claim 8, further comprising a plurality of power amplifier circuits each configured to amplify a respective one of a plurality of radio frequency (RF) signals based on a respective one of the plurality of voltages for transmission in one of frequency range two (FR2) and frequency range three (FR3).

16. The wireless device of claim 15, further comprising:
a power management integrated circuit (PMIC) configured to generate a modulated voltage; and
a plurality of second power amplifier circuits each configured to amplify a respective one of the plurality of RF signals based on the modulated voltage for transmission in frequency range one (FR1).

17. The wireless device of claim 16, wherein the PMIC is further configured to generate and provide the reference voltage to the SIMO voltage circuit when the plurality of RF signals is transmitted exclusively in one of FR2 and FR3.

18. A method for concurrently generating multiple voltages comprising:
receiving a reference voltage multiplexed to indicate a respective one of a plurality of marked-up target voltages of a respective one of a plurality of voltages in a respective one of a plurality of voltage steps during a voltage generation cycle;
discharging, in each of the plurality of voltage steps during the voltage generation cycle, a respective one of a plurality of holding capacitors configured to maintain the respective one of the plurality of voltages in the respective one of the plurality of voltage steps;
recharging, in each of the plurality of voltage steps during the voltage generation cycle, concurrently all remaining ones of the plurality of holding capacitors during the respective one of the plurality of voltage steps;
determining a respective one of a plurality of real target voltages of the respective one of the plurality of voltages from the respective one of the plurality of marked-up target voltages; and
regulating the respective one of the plurality of voltages to match the respective one of the plurality of real target voltages.
